(19) United States
(12) Patent Application Publication
(10) Pub. No.: US 2024/0347354 A1
(43) Pub. Date: Oct. 17, 2024

(54) HEAT-TREATING METHOD, HEAT-TREATING APPARATUS, AND STORAGE MEDIUM

(71) Applicant: Tokyo Electron Limited, Tokyo (JP)

(72) Inventors: Ryouichirou NAITOU, Koshi City (JP); Shinichiro KAWAKAMI, Hillsboro, OR (US); Tomoya ONITSUKA, Koshi City (JP); Soichiro OKADA, Leuven (BE); Satoru SHIMURA, Koshi City (JP)

(21) Appl. No.: 18/632,500

(22) Filed: Apr. 11, 2024

(30) Foreign Application Priority Data
Apr. 14, 2023 (JP) 2023-066388

(51) Int. Cl. H01L 21/67; G03F 7/38; H01L 21/027

(52) U.S. Cl. CPC H01L 21/67109; H01L 21/0274; H01L 21/67017; G03F 7/38

(57) ABSTRACT

A heat-treating method of performing a heat treatment on a substrate on which a film of a metal-containing resist film is formed and which is subjected to an exposure treatment, includes an operation of heating the substrate for a predetermined period of time at a heating temperature at which a metal-containing sublimate is not generated from the film of the metal-containing resist, wherein during the operation of heating the substrate, a reactive fluid in which a concentration of at least one of a carbon dioxide or moisture is higher than a concentration in an atmosphere to promote a reaction within the film of the metal-containing resist, is supplied to a processing space around the substrate.

### CROSS-REFERENCE TO RELATED APPLICATION

This application is based upon and claims the benefit of priority from Japanese Patent Application No. 2023-066388, filed on Apr. 14, 2023, the entire contents of which are incorporated herein by reference.

### TECHNICAL FIELD

The present disclosure relates to a heat-treating method, a heat-treating apparatus, and a non-transitory computer-readable storage medium.

### BACKGROUND

Patent Document 1 discloses a heat-treating apparatus which thermally treats a metal-containing film formed on a substrate. The heat-treating apparatus includes a processing chamber which accommodate the substrate, a heat treatment plate which is provided inside the processing chamber and places the substrate thereon, a moisture supplier which supplies moisture to the metal-containing film, and a central exhauster which exhausts gas inside the processing chamber from a central portion of the processing chamber.

### PRIOR ART DOCUMENTS

### Patent Documents

Patent Document 1: Japanese Patent Laid-Open Publication No. 2018-098229

### SUMMARY

According to one embodiment of the present disclosure, a heat-treating method of performing a heat treatment on a substrate on which a film of a metal-containing resist film is formed and which is subjected to an exposure treatment, includes an operation of heating the substrate for a predetermined period of time at a heating temperature at which a metal-containing sublimate is not generated from the film of the metal-containing resist, wherein during the operation of heating the substrate, a reactive fluid in which a concentration of at least one of a carbon dioxide or moisture is higher than a concentration in an atmosphere to promote a reaction within the film of the metal-containing resist, is supplied to a processing space around the substrate.

### BRIEF DESCRIPTION OF DRAWINGS

The accompanying drawings, which are incorporated in and constitute a part of the specification, illustrate embodiments of the present disclosure, and together with the general description given above and the detailed description of the embodiments given below, serve to explain the principles of the present disclosure.

FIG. 1 is a diagram showing a relationship between an amount of metal generated from a film of a metal-containing resist, a heating time, and a heating temperature.

FIG. 2 is a plan view schematically showing an outline of a configuration of a wafer processing system as a substrate processing system, which includes a heat-treating apparatus according to an embodiment.

FIG. 3 is a front view schematically showing the outline of the configuration of the wafer processing system as the substrate processing system, which includes the heat-treating apparatus according to the embodiment.

FIG. 4 is a longitudinal cross-sectional view schematically showing a configuration of the heat-treating apparatus used for a PEB treatment.

FIG. 5 is a bottom view schematically showing a configuration of an upper chamber.

FIGS. 6A and 6B are diagrams showing a state of the heat-treating apparatus during a wafer processing performed using the heat-treating apparatus of FIG. 4.

FIGS. 7A and 7B are diagrams showing a state of the heat-treating apparatus during the wafer processing performed using the heat-treating apparatus of FIG. 4.

FIG. 8 is a diagram showing a state of the heat-treating apparatus during the wafer processing performed using the heat-treating apparatus of FIG. 4.

FIG. 9 is a diagram showing a relationship between a space width of a line-and-space resist pattern obtained by a PEB treatment and a concentration of a carbon dioxide in an ambient atmosphere of a chamber in Comparative Example.

FIG. 10 is a diagram showing a relationship between the space width of the line-and-space resist pattern obtained by the PEB treatment and a concentration of moisture of the ambient atmosphere of the chamber in the Comparative Example.

FIG. 11 is a diagram showing an example of a reactive gas supply mechanism.

### DETAILED DESCRIPTION

Reference will now be made in detail to various embodiments, examples of which are illustrated in the accompanying drawings. In the following detailed description, numerous specific details are set forth in order to provide a thorough understanding of the present disclosure. However, it will be apparent to one of ordinary skill in the art that the present disclosure may be practiced without these specific details. In other instances, well-known methods, procedures, systems, and components have not been described in detail so as not to unnecessarily obscure aspects of the various embodiments.

In a manufacturing process of a semiconductor device or the like, a predetermined process is performed on a substrate such as a semiconductor wafer (hereinafter referred to as a “wafer”) to form a resist pattern on the substrate. Examples of the predetermined process may include a resist coating process of applying a resist solution onto the substrate to form a resist film, an exposure treatment of exposing the film, a developing treatment of developing the film and the like. Further, the predetermined process may include a heat treatment such as a post exposure bake (PEB) process of heating the substrate after the exposure treatment and before the developing treatment.

In recent years, there is a case in which a metal-containing resist is used as a resist instead of a chemically-amplified resist. In this case, the PEB treatment is performed by heating the substrate at, for example, 180 degrees C., for a predetermined period of time. Further, the PEB treatment is performed while supplying a moisture-containing gas into a chamber that accommodates the substrate that is being processed. Further, in the PEB treatment, a metal-containing sublimate occurs from a film of the metal-containing resist when the substrate is heated at a temperature of 180 degrees C. Therefore, an interior of the chamber is exhausted to collect such a metal-containing sublimate. This is because if the substrate or the device is contaminated by the metal-containing sublimate, electrical characteristics of the semiconductor device is affected.

However, in a PEB treatment in the related art on the substrate on which the metal-containing resist film is formed, it is difficult to achieve both an in-plane uniformity in dimensions of a metal-containing resist pattern and suppression of contamination of the substrate or other devices caused by the metal-containing sublimate. To address these, it is important not to collect the metal-containing sublimate generated by the PEB treatment by exhaust, but to prevent the metal-containing sublimate from occurring by the PEB treatment from the beginning.

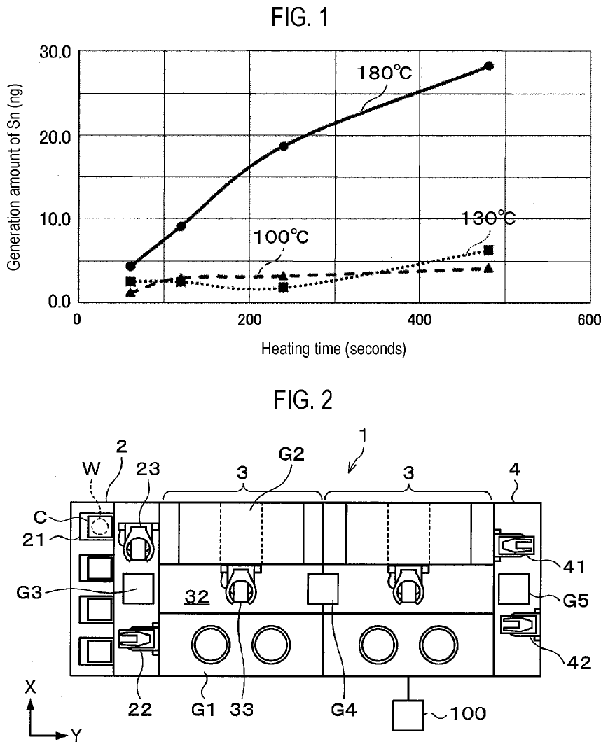

Therefore, the present inventors conducted an experimentation to check a relationship between an amount of metal (specifically, tin (Sn)) generated from the metal-containing resist film caused by heating, a heating time (that is, a processing time), and a heating temperature. The results are shown in FIG. 1. In the above experimentation, the heating time was set to 60 seconds, 120 seconds, 240 seconds, and 480 seconds.

As shown in FIG. 1, when a heating temperature is 100 degrees C., the amount of generated Sn was increased until the heating time reaches 120 seconds, but was not changed when the heating times are 120 seconds and 240 seconds. Subsequently, the amount of generated Sn was increased when the heating time reaches 480 seconds. On the other hand, when the heating temperature is 180 degrees C., the amount of generated Sn was continued to increase according to the heating time. Further, when the heating temperature is 130 degrees C., the amount of generated Sn was not changed until the heating time reaches 240 seconds. That is, the generation of Sn temporarily stopped until the heating time reaches 60 seconds. Further, when the heating temperature is 130 degrees C., the amount of generated Sn was increased after the heating time becomes 480 seconds.

From the above-described experimentation results, it is assumed that a stage in which Sn is generated from the metal-containing resist film includes a first stage in which Sn vaporizes together with a solvent of the metal-containing resist, and a second stage in which Sn vaporizes together with a solute of the metal-containing resist, that is, a Sn-containing sublimate is generated. In the above experimentation, when the heating temperature is 180 degrees C., since the heating time is short, the second stage begins. Thus, as described above, it is thought that the amount of generated Sn continues to increase according to the heating time. Further, at the heating temperature of 100 degrees C., it is thought that the first stage is kept until a timing of any one of the heating times of 60 seconds and 120 seconds, and the second stage begins from a timing of any one of the heating times of 240 seconds and 480 seconds. On the other hand, at the heating temperature of 130 degrees C., it is thought that the first stage ends before the heating time reaches 60 seconds, and the second stage begins from a timing of any one of the heating times of 240 seconds and 480 seconds.

Based on the above experimentation results, as a method of preventing the metal-containing sublimate from occurring by the PEB treatment, a method of allowing the second stage so as not to begin during the PEB treatment, that is, a method of performing the heating at a low temperature at which the metal-containing sublimate is not generated during the PEB treatment, may be considered. However, when the temperature during the PEB treatment is low, the PEB treatment may not be performed at a good level. Specifically, for example, when the temperature during the PEB treatment is low, an exposure sensitivity may be degraded, that is, an exposure amount may not be increased. This may result in an insufficient reaction within the metal-containing resist film by the PEB treatment. Such an insufficient reaction makes it difficult to obtain a pattern of the metal-containing resist with desired dimensions when the developing treatment is performed after the PEB treatment.

Therefore, a technique according to the present disclosure performs a PEB treatment on a substrate at a good level while suppressing the substrate or other devices from contaminating by a metal-containing sublimate when a heat treatment, that is, the PEB treatment, on the substrate on which a metal-containing resist film is formed and to which an exposure treatment is subjected.

Hereinafter, a heat-treating method and a heat-treating apparatus according to an embodiment will be described with reference to the drawings. In the present specification, elements having substantially the same functional configuration are denoted by the same reference numerals and thus redundant descriptions will be omitted.

### <Wafer Processing System>

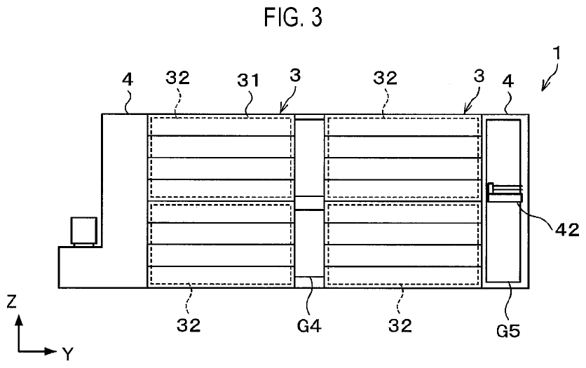

First, a configuration of a wafer processing system as a substrate processing system which includes the heat-treating apparatus according to an embodiment, will be described. FIGS. 2 and 3 are a plan view and a front view schematically showing an outline of the configuration of a wafer processing system 1 according to the embodiment, respectively. In the embodiment, a description will be given by way of an example in which the wafer processing system 1 is a photolithography processing system which performs a resist film forming process and a developing treatment on a wafer W.

As shown in FIG. 1, the wafer processing system 1 includes a cassette station 2 into or out of which a cassette C accompanying a plurality of wafers W is carried, and a processing station 3 equipped with a plurality of various processing apparatuses which performs a predetermined process on the wafers W. The wafer processing system 1 has a configuration in which the cassette station 2, the processing station 3, and an interface station 4 which delivers the wafers W to or from a peripheral exposure apparatus (not shown) adjacent on the opposite side of the processing station 3 are integrally connected together. In addition, although two processing stations 3 are shown to be installed between the cassette station 2 and the interface station 4 in FIG. 1, the number of processing stations 3 installed may be one or may be three or more.

The cassette station 2 is provided with a plurality of cassette placement plates 21 and wafer transfer devices 22 and 23. The cassette station 2 transfers the wafers between the cassette C placed on the cassette placement plate 21 and the processing station 3 by the wafer transfer device 22 or 23. To do this, each of the wafer transfer devices 22 and 23 may include a drive mechanism which is movable in an X direction, a Y direction or a vertical direction and rotatable around a vertical axis (movable in a θ direction) as necessary. Alternatively, each of the wafer transfer devices 22 and 23 may include a drive mechanism operable in all directions. At least one of the wafer transfer device 22 or 23 may deliver the wafers W to or from the cassette C and may deliver the wafers W to or from the processing station 3. The operation of delivering the wafers W to or from the processing station 3 means, for example, delivering the wafers W to or from a third block G3 provided with a delivery device that is accessible by a wafer transfer device 33 in the processing station 3, which will be described later. For example, the third block G3 is provided inside the cassette station 2 and may include a plurality of delivery devices (not shown) arranged in the vertical direction.

An inspection device (not shown) for inspecting the wafers W may be provided at a position accessible by any one of the wafer transfer devices 22 and 23.

The processing station 3 is provided with a plurality of (for example, three) blocks, such as first, second, and fourth blocks G1, G2, and G4. Further, as shown in FIG. 3, a plurality of layers 31 in which the first and second blocks G1 and G2 are provided is stacked in the vertical direction. For example, the first block G1 is provided on a front side of the processing station 3 (in a negative X-direction in FIG. 1), and the second block G2 is provided on a rear side of the processing station 3 (in a positive X-direction in FIG. 1). The fourth block G4 is provided on the side of the interface station 4 of the processing station 3 (in a positive Y-direction in FIG. 1) or at a connection portion with another adjacent processing station 3. The fourth block G4 may include a plurality of delivery devices arranged in the vertical direction. Further, the third block G3 described above may be provided within the processing station 3.

In the first block G1, a plurality of processing apparatuses, for example, a patterning film forming apparatus and a developing apparatus (both not shown) are arranged. The patterning film forming apparatus may include, for example, an anti-reflection film forming apparatus in addition to a resist film forming apparatus.

For example, the plurality of processing apparatuses is arranged in a horizontal direction. The number, arrangements, and types of these processing apparatuses may be arbitrarily selected.

In the patterning film forming apparatus and the developing apparatus, processing is performed, for example, by supplying a predetermined processing liquid or a predetermined gas onto the wafer W. In this way, the patterning film forming apparatus forms a resist film used as a mask when forming a pattern of an underlying film or forms an anti-reflection film for efficiently performing light irradiation processing such as the exposure treatment. On the other hand, in the developing apparatus, a portion of an exposed resist film is removed to form an uneven shape as the mask.

For example, in the second block G2, heat-treating apparatuses (not shown) which perform heat treatment such as heating and cooling of the wafer W are provided in the vertical direction and the horizontal direction. Although not all shown, the second block G2 is also provided with a hydrophobizing apparatus which performs a hydrophobizing process to raise fixation of a resist solution to the wafer W, and a peripheral exposure apparatus that exposes an outer periphery of the wafer W, which are arranged in the vertical direction (Z direction in FIG. 3) and horizontal direction. The numbers and arrangements of heat-treating apparatus, hydrophobizing apparatus, and peripheral exposure apparatus may also be arbitrarily selected.

As shown in FIG. 2, a wafer transfer area 32 is formed in an area sandwiched between the first block G1 and the second block in a plan view. For example, the wafer transfer device 33 is arranged in the wafer transfer area 32.

The wafer transfer device 33 includes a transfer arm 70a which is movable, for example, in a Y direction, a front-rear direction, a θ direction, and a vertical direction. The wafer transfer device 33 moves within the wafer transfer area 32 and may transfer the wafer W to a predetermined device in the first block G1, the second block G2, the third block G3, and the fourth block G4. When a plurality of processing stations 3 are provided as shown in FIG. 2, the wafer transfer device 33 provided in the processing station 3 located on the side of the interface station 4 may transfer the wafer W to a predetermined device in a fifth block G5 (to be described later) in addition to the devices in the first, second, and fourth blocks G1, G2, and G3.

For example, a plurality of wafer transfer devices 33 is vertically arranged. One wafer transfer device 33 may transfer the wafer W to a predetermined device located at the height of a plurality of layers 31 in an upper layer among the plurality of layers 31 stacked vertically. Another wafer transfer device 33 may transfer the wafer W to a predetermined device located at the height of a plurality of layers 31 located below the layers 31 in the upper layer. A plurality of wafer transfer areas 32 in which the transfer of the wafer W is possible may be provided. The number of wafer transfer devices 33 and the number of layers 31 corresponding to one wafer transfer device 33 may be arbitrarily selected, such as providing a wafer transfer device 33 for each layer 31.

Further, a shuttle transfer device (not shown) may be provided in the wafer transfer area 32, the first block G1, or the second block G2. The shuttle transfer device linearly transfers the wafer W between a space adjacent to one side of the processing station 3 and another space adjacent to the opposite side of the processing station 3.

The interface station 4 is provided with the fifth block G5 including a plurality of delivery devices, and wafer transfer devices 41 and 42. The interface station 4 transfers the wafer W using the wafer transfer device 41 or the wafer transfer device 42, between the fifth block G5 in which the wafer W is delivered by the wafer transfer device 33 and the exposure apparatus. To do this, each of the wafer transfer devices 41 and 42 is equipped with drive mechanisms movable in the X direction, the Y direction, the vertical direction, and rotatable around the vertical axis (the θ direction) as necessary, and may be provided with drive mechanisms operable in all directions. At least one of the wafer transfer device 41 or 42 may support the wafer W and transfer the wafer W between the delivery device and the exposure apparatus in the fifth block G5.

A cleaning apparatus for cleaning the front surface of the wafer W and the above-mentioned peripheral exposure apparatus may be provided at a position accessible by any one of the wafer transfer devices 41 and 42 in the interface station 4.

The wafer processing system 1 described above is provided with a controller 100. The

controller 100 is, for example, a computer, and includes a program storage (not shown). The program storage stores a program for controlling the processing on the wafer W in the wafer processing system 1. The program storage also stores a program for achieving a wafer processing in the wafer processing system 1 by controlling operations of drive systems such as the above-described various processing apparatuses or transfer devices. The programs may be recorded in a non-transitory computer-readable storage medium H, and may be installed in the controller 100 from the storage medium H.

### <Operation of Wafer Processing System>

The wafer processing system 1 is configured as described above. Next, an example of the wafer processing performed using the wafer processing system 1 configured as described above will be described.

First, the cassette C accommodating the plurality of wafers W is carried into the cassette station 2 of the wafer processing system 1 and placed on the cassette placement plate 21. Then, the wafers W in the cassette C are sequentially taken out by the wafer transfer device 22 or 23 and transferred to the delivery device of the third block G3.

The wafer W transferred to the delivery device of the third block G3 is supported by the wafer transfer device 33 and transferred to the hydrophobizing apparatus provided in the second block G2 where the wafer W is subjected to a hydrophobizing process. Subsequently, the wafer W is transferred by the wafer transfer device 33 to the resist film forming apparatus where a resist film is formed on the wafer W. Thereafter, the wafer W is transferred to the heat-treating apparatus where the wafer W is prebaked and then is transferred to the delivery device of the fifth block G5. When the plurality of processing stations 3 are provided as shown in FIGS. 2 and 3, the wafer W is placed once on the delivery device of the fourth block G4 before being transferred to the delivery device of the fifth block G5, and then the wafer W is delivered between the plurality of wafer transfer devices 33. Further, the wafer W may be transferred by the wafer transfer device 33 to the peripheral exposure apparatus as necessary in which the exposure treatment is performed on the peripheral portion of the wafer W.

The wafer W transferred to the delivery device of the fifth block G5 is transferred by the wafer transfer device 41 or 42 to the exposure apparatus where the wafer W is subjected to the exposure treatment in a predetermined pattern. The wafer W may be cleaned by the cleaning apparatus before the exposure treatment.

The exposed wafer W is transferred to the delivery device of the fifth block G5 by the wafer transfer device 41 or the wafer transfer device 42. Thereafter, the wafer W is transferred by the wafer transfer device 33 to the heat-treating apparatus where the wafer W is subjected to the PEB treatment.

The wafer W that has been subjected to the PEB treatment is transferred by the wafer transfer device 33 to the developing apparatus where the wafer W is developed. After the developing treatment, the wafer W is transferred by the wafer transfer device 33 to the heat-treating apparatus where the wafer W is subjected to a post-baking treatment.

Thereafter, the wafer W is transferred to the delivery device of the third block G3 by the wafer transfer device 33 and then transferred to the cassette C of the cassette placement plate 21 by the wafer transfer device 22 or 23 of the cassette station 2. In this way, a series of photolithography processes is completed.

### <Type of Resist>

In the wafer processing system 1 of the present disclosure, a film of the resist formed on the wafer W by the resist film forming apparatus, that is, a resist film, is a film of a metal-containing resist, that is, a metal-containing resist film. Further, the metal contained in the metal-containing resist is optional, and is, for example, tin. The metal-containing resist used in the wafer processing system 1 is, for example, a negative type resist.

### <Heat-Treating Apparatus>

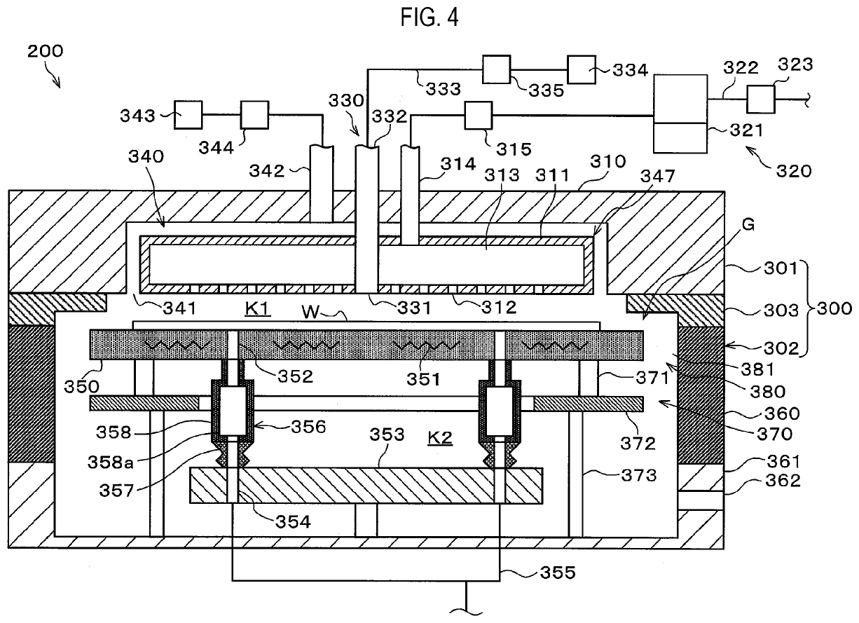

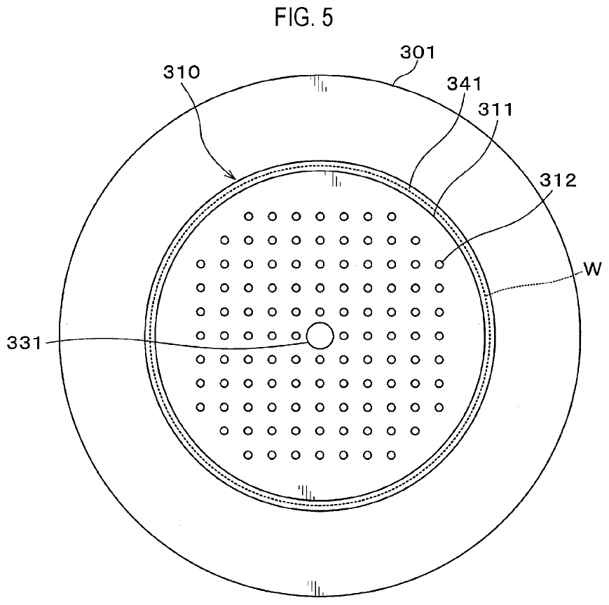

Next, among the above-mentioned heat-treating apparatuses, a heat-treating apparatus used for the post-exposure bake treatment, that is, the PEB treatment, will be described. FIG. 4 is a longitudinal cross-sectional view schematically showing a configuration of a heat-treating apparatus 200 used for the PEB treatment. FIG. 5 is a bottom view schematically showing a configuration of an upper chamber 301, which will be described later.

The heat-treating apparatus 200 in FIG. 4 includes a chamber 300 which provides a processing space K1 in which the wafer W under a heat treatment (specifically, the PEB treatment) is accommodated. The chamber 300 includes the upper chamber 301, a lower chamber 302, and a rectifying member 303. The upper chamber 301 is located on an upper side, and the lower chamber 302 is located on a lower side. The rectifying member 303 is located between the upper chamber 301 and the lower chamber 302, and specifically, is located between a peripheral portion of the upper chamber 301 and a peripheral portion of the lower chamber 302.

The upper chamber 301 is configured to be movable up and down. An elevating mechanism (not shown) having a drive source such as a motor, which raises and lowers the upper chamber 301, is controlled by the controller 100. In addition, the upper chamber 301 is formed in, for example, a disc shape. The upper chamber 301 has a ceiling portion 310. The processing space K1 is formed below the ceiling portion 310. The ceiling portion 310 is provided to face the wafer W on a hot plate 350 described later. Further, the ceiling portion 310 is provided with a shower head 311 as a supplier.

The shower head 311 supplies, into the processing space K1, a reactive gas as a reactive fluid which promotes a reaction within the metal-containing resist film. Specifically, the shower head 311 supplies the reactive gas from the ceiling portion 310 to the wafer W on the hot plate 350 accommodated in the processing space K1. The reactive gas is a gas in which the concentration of at least one of carbon dioxide or moisture is higher than that in an ambient atmosphere. The concentration of the carbon dioxide in the reactive gas is, for example, 450 ppm or more and 10,000 ppm or less. Further, the concentration of the moisture, that is, the humidity of the reactive gas is, for example, 40% or more and 90% or less. The shower head 311 has a plurality of discharge holes 312 and a gas distribution space 313.

Each of the discharge holes 312 is formed in the bottom surface of the shower head 311. For example, as shown in FIG. 5, the discharge holes 312 are arranged substantially uniformly at a central portion of the bottom surface of the shower head 311, except for an exhaust port 331 (to be described later).

In the gas distribution space 313, the reactive gas introduced into the shower head 311 is distributed and is supplied to each discharge hole 312. As shown in FIG. 4, a supply mechanism 320 is connected to the shower head 311 via a supply pipe 314.

The supply mechanism 320 supplies the reactive gas to the shower head 311 (specifically, the gas distribution space 313). Further, the supply mechanism 320 includes, for example, a tank 321 that stores carbonated water as a reactive raw material and a supply pipe 322 that supplies a carrier gas to the tank 321 and supplies a mixed gas of the carbonated water vapor and the carrier gas. The tank 321 may be provided with a heater (not shown) that heats the carbonated water to promote vaporization of the carbonated water. Alternatively, the carbonated water may be vaporized using the carrier gas for bubbling the carbonated water in the tank 321. The carrier gas is, for example, a nitrogen gas, a compressed air, a carbon dioxide gas, or a mixture thereof. The supply pipe 322 is provided with a supply equipment group 323 including an opening/closing valve, a flow rate control valve, and the like, which control a flow of the carrier gas. Further, the supply pipe 314 is provided with a supply equipment group 315 including an opening/closing valve, a flow rate control valve, and the like, which control a flow of the reactive gas. The supply equipment groups 315 and 323 are controlled by the controller 100.

Further, the ceiling portion 310 of the upper chamber 301 is provided with a central exhauster 330. The central exhauster 330 and a peripheral exhauster 340 (to be described later) constitute an exhauster which exhausts an interior of the processing space K1.

The central exhauster 330 exhausts the processing space K1 above the hot plate 350 within the chamber 300 from a position of the ceiling portion 310 near the center (from a central position in the example shown in the drawing) when viewed from the upper surface of the wafer W on the hot plate 350, that is, from above the center when viewed from the upper surface of the wafer W on the hot plate 350. The central exhauster 330 has an exhaust port 331. As shown in FIG. 5, the exhaust port 331 is provided at a position on the bottom surface of the shower head 311 near the center (at the central position in the example of the drawing) when viewed from the upper surface of the wafer W on the hot plate 350, and is open downward. The central exhauster 330 exhausts the interior of the processing space K1 through the exhaust port 331.

As shown in FIG. 4, the central exhauster 330 includes a central exhaust passage 332 formed to extend upward from the exhaust port 331. An exhaust device 334 such as a vacuum pump is connected to the central exhaust passage 332 via an exhaust pipe 333. The exhaust pipe 333 is provided with an exhaust equipment group 335 including a valve for adjusting an amount of exhaust. The exhaust device 334 and the exhaust equipment group 335 are controlled by the controller 100.

Further, the ceiling portion 310 of the upper chamber 301 is provided with the peripheral exhauster 340. The peripheral exhauster 340 exhausts the processing space K1 from a position of the ceiling portion 310 closer to the peripheral portion of the wafer W on the hot plate 350 than the central exhauster 330, when viewed from the upper surface, that is, from above the peripheral portion when viewed from the upper surface of the wafer W on the hot plate 350. The peripheral exhauster 340 has an exhaust port 341. As shown in FIG. 5, the exhaust port 341 is opened downward from the bottom surface of the ceiling portion 310 so as to surround the outer periphery of the shower head 311. The exhaust port 341 may have a plurality of exhaust holes arranged along the outer periphery of the shower head 311. The peripheral exhauster 340 exhausts the interior of the processing space K1 via the exhaust port 341.

The peripheral exhauster 340 in FIG. 4 includes a peripheral exhaust passage extending

from the exhaust port 341. An exhaust device 343 such as a vacuum pump is connected to the peripheral exhaust passage via an exhaust pipe 342. The exhaust pipe 342 is provided with an exhaust equipment group 344 including a valve for adjusting an amount of exhaust. The exhaust device 343 and the exhaust equipment group 344 are controlled by the controller 100.

The lower chamber 302 is provided to surround surroundings of the hot plate 350 (specifically, sides of the hot plate 350 and below the hot plate 350) serving as a heater which supports and heats the wafer W.

The hot plate 350 has a thick disc shape. Further, the hot plate 350 includes a built-in heater 351, for example. A temperature of the hot plate 350 is adjusted, for example, by controlling the heater 351 by the controller 100 so that the wafer W placed on the hot plate 350 is heated to a predetermined temperature.

Further, the hot plate 350 has, for example, a plurality of adsorption holes 352 for adsorbing the wafer W onto the hot plate 350. Each adsorption hole 352 is formed to pass through the hot plate 350 in a thickness direction. Further, each adsorption hole 352 is connected to a relay hole 354 of a relay member 353. The relay hole 354 is connected to an exhaust line 355 through which exhaust for adsorption is performed.

The adsorption hole 352 and the relay hole 354 are connected to each other via a metal member 356 and a resin pad 357. Specifically, the adsorption hole 352 and the relay hole 354 are connected to each other via a flow passage in the metal member 356 and a flow passage in the resin pad 357.

The metal member 356 is located near the adsorption hole 352, and the resin pad 357 is located near the relay hole 354. One end of the metal member 356 is directly connected to the hot plate 350 (specifically, the adsorption hole 352), and the other end thereof is directly connected to one end of the corresponding resin pad 357. In other words, each resin pad 357 communicates with the corresponding adsorption hole 352 via the metal member 356 and is connected to the hot plate 350 via the metal member 356. Further, the other end of the resin pad 357 is directly connected to the relay member 353 (specifically, the relay hole 354).

The metal member 356 has an increased-diameter portion 358 near the resin pad 357. An interior of the increased-diameter portion 358 provides a flow passage space 358a having a larger cross-sectional area than a portion of the metal member 356 connected to the hot plate 350, thereby reducing the risk of clogging due to a sublimate generated during the heat treatment. Further, due to the passage space 358a having the large cross-sectional area, heat of gas suctioned from the processing space K1 when the wafer W is reduced and is radiated toward the exhaust line 355 for adsorption. In other words, it is possible to suppress the risk of deterioration in a device constituting an exhaust flow passage extending up to the resin pad 357 or the exhaust line 355, due to high temperature.

The exhaust line 355 is provided with an exhaust device (not shown) such as a vacuum pump and an exhaust amount adjustment equipment group (not shown) including a valve. The exhaust device and the exhaust amount adjustment equipment group are controlled by the controller 100.

Further, lifting pins (not shown), for example, three lifting pins, which support the wafer W from below and lift the wafer W up, are provided below the hot plate 350 in the lower chamber 302. The lifting pins are raised and lowered by a lifting mechanism (not shown) having a drive source such as a motor. This lifting mechanism is controlled by the controller 100. Through-holes (not shown) through which the lifting pins pass are formed in the center of the hot plate 350. The lifting pins may pass through the through-holes and protrude from the upper surface of the hot plate 350.

Further, the lower chamber 302 includes a support ring 360 and a bottom chamber 361.

The support ring 360 has a cylindrical shape. A material of the support ring 360 is, for example, metal such as stainless steel. The support ring 360 covers an outer surface of the hot plate 350. The support ring 360 is fixed to the bottom chamber 361.

The bottom chamber 361 has a cylindrical shape with a bottom. The aforementioned hot plate 350 is supported on, for example, a bottom wall of the bottom chamber 361.

Specifically, the hot plate 350 is supported by a bottom wall of the bottom chamber 361 via a supporter 370. The supporter 370 includes, for example, a support column 371, an upper end of which is connected to the hot plate 350, an annular member 372 which supports the support column 371, and a leg member 373 which supports the annular member 372 on the bottom wall of the bottom chamber 361.

The annular member 372 is made of metal and is provided below a back surface of the hot plate 350 with a gap corresponding to a height of the support column 371 left from the back surface. By positioning the resin pad 357 below the annular member 372 provided as above, heat from the hot plate 350 is effectively blocked by the annular member 372 so that the resin pad 357 is hardly exposed to the high temperature (that is, is hardly thermally deteriorated).

In addition, the lower chamber 302 has an introduction port 362. The introduction port 362 introduces gas into the chamber 300 from the outside of the chamber 300. The introduction port 362 is formed in, for example, a cylindrical sidewall of the bottom chamber 361. An inner peripheral surface of the sidewall of the bottom chamber 361 and an inner peripheral surface of the support ring 360 are equal in diameter to each other.

Further, the heat-treating apparatus 200 includes a supplier 380. The supplier 380 supplies the gas introduced into the chamber 300 via the introduction port 362 to the wafer W on the hot plate 350 from a lateral side of the wafer W on the hot plate 350 and from a lower portion of the processing space K1 (specifically, below the front surface (that is, the upper surface) of the wafer W).

Further, the supplier 380 includes a gas flow passage 381 provided to surround a lateral surface of the hot plate 350, and the rectifying member 303.

The gas flow passage 381 is constituted by, for example, a space between an outer surface of the hot plate 350 and an inner peripheral surface of the support ring 360. Therefore, the gas flow passage 381 is formed in, for example, an annular shape in a plan view. The outer surface of the hot plate 350 is supported on an inner peripheral surface of the sidewall of the lower chamber 302 via a support member. A plurality of through-holes which open in the vertical direction may be provided in the support member in an annular shape. The plurality of through-holes may be used as the gas flow passage 381.

The rectifying member 303 is a member which directs the gas rising along the gas flow passage 381 toward the wafer W on the hot plate 350.

The rectifying member 303 is formed in, an annular shape in a plan view. A bottom surface of an inner periphery of the rectifying member 303 serves as a guide surface that directs the gas rising along the gas flow passage 381 toward the center of the hot plate 350. An inner peripheral edge of the bottom surface of the rectifying member 303 is located at a height equal to or less than a half of the height of the processing space K1, that is, at a height equal to or less than a half of a height from the front surface of the hot plate 350 on which the wafer W is placed to the bottom surface of the shower head 311 which is provided with the discharge holes 312 and faces the wafer W on the hot plate 350. For example, the inner peripheral edge of the bottom surface of the rectifying member 303 is located below the front surface of the wafer W on the hot plate 350. An inner peripheral portion of the rectifying member 303 overlaps a peripheral portion of the hot plate 350 when viewed from the top and does not overlap the wafer W on the hot plate 350 when viewed from the top. The gas rising along the gas flow passage 381 passes through a gap G between the bottom surface of the inner periphery of the rectifying member 303 and the upper surface of the peripheral portion of the hot plate 350, and is directed toward the wafer W from the lateral side of the wafer W on the hot plate 350 in the processing space K1. Assuming that a space above the surface of the hot plate 350 is the processing space K1, the gap G through which gas flows into the processing space K1 is provided at a lower portion of the processing space K1.

The gap G is connected to one end of the gas flow passage 381. Further, the other end of the gas flow passage 381 is connected to a buffer space K2 below the hot plate 350 in the chamber 300. The buffer space K2 below the hot plate 350 has a larger volume than the processing space K1 above the hot plate 350.

An inner peripheral surface of the rectifying member 303 extends linearly downward from the ceiling portion 310 of the upper chamber 301.

In an embodiment, the rectifying member 303 is a solid body. A material of the rectifying member 303 is, for example, a metal material such as stainless steel. Further, the entire upper surface of the rectifying member 303 contacts the bottom surface of the upper chamber 301. More specifically, the rectifying member 303 is fixed to the upper chamber 301, the entire upper surface of which is in contact with the bottom surface of the upper chamber 301, and moves up and down together with the upper chamber 301.

The rectifying member 303 descends together with the upper chamber 301 and comes into contact with the lower chamber 302 (specifically, the support ring 360), thereby closing the chamber 300.

The heat-treating apparatus 200 may further include a cooling plate (not shown) having a function of cooling the wafer W. The cooling plate reciprocally moves, for example, between a cooling position outside the chamber 300 and a delivery position. At least a portion of the delivery position is located inside the chamber 300 to deliver the wafer W between the cooling plate and the hot plate 350. Alternatively, the cooling plate may be fixed at a position parallel to the hot plate 350 in a horizontal direction, and the heat-treating apparatus 200 may have a transfer arm which transfers the wafer W between the cooling plate and the hot plate 350.

### <Wafer Processing Using Heat-Treating Apparatus 200>

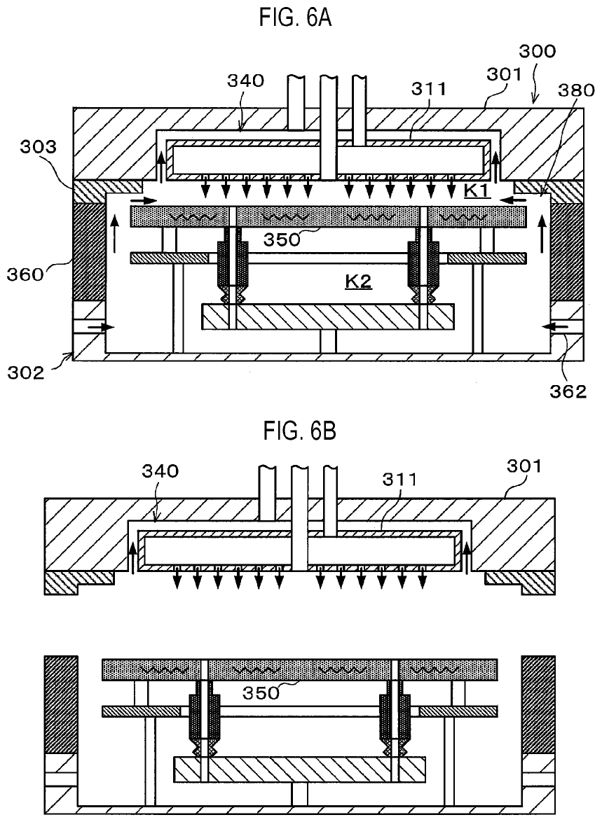

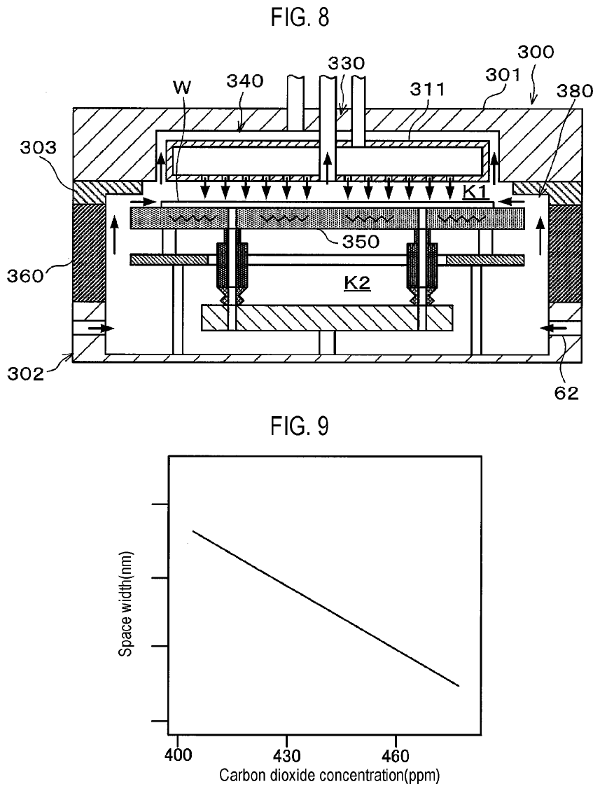

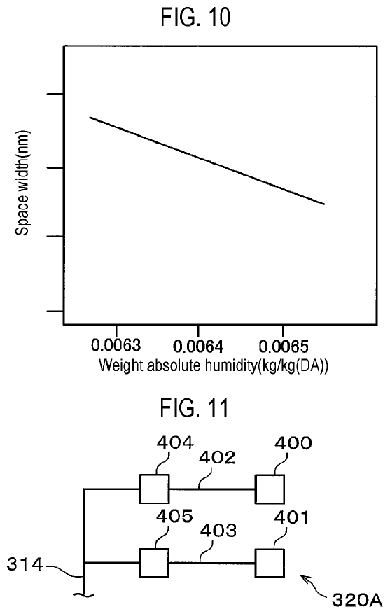

Next, an example of the wafer processing performed using the heat-treating apparatus 200 will be described with reference to FIGS. 6A to 10. FIGS. 6A to 8 are diagrams showing a state of the heat-treating apparatus 200 during the wafer processing performed using the heat-treating apparatus 200. FIG. 9 is a diagram showing a relationship between a space width (critical dimension CD) of a line-and-space resist pattern obtained by the PEB treatment and a concentration of carbon dioxide in an ambient atmosphere of the chamber 300 in Comparative Example described later. FIG. 10 is a diagram showing the relationship between the space width and a humidity, that is, a concentration of moisture in the ambient atmosphere of the chamber 300. In FIGS. 9 and 10, each scale on the vertical axis is equivalent to 0.5 nm. The following wafer processing is performed under the control of the controller 100.

### (Step S1: Adjusting Internal State of Chamber)

First, for example, prior to placing the wafer W on the hot plate 350, an internal state of the chamber 300 is adjusted. Specifically, as shown in FIG. 6A, the upper chamber 301 is lowered so that the rectifying member 303 comes into contact with the support ring 360 of the lower chamber 302, that is, the chamber 300 is brought into a closed state. Then, the hot plate 350 is adjusted to have a predetermined temperature in a state in which the processing space K1 is formed. Further, the concentration of the carbon dioxide and the humidity within the processing space Kl are adjusted. The adjustment of the concentration of the carbon dioxide and the humidity in the processing space K1 is performed by, for example, continuously performing the exhaust by the peripheral exhauster 340 and the supply of the reactive gas from the shower head 311 for a predetermined period of time. In this process, the exhaust by the peripheral exhauster 340 and the supply of the reactive gas from the shower head 311 may be performed so that gas is supplied from the supplier 380. Specifically, for example, an exhaust flow rate L2 of gas exhausted from the processing space K1 by the peripheral exhauster 340 may be controlled to be larger than a discharge flow rate L1 of gas discharged from the shower head 311 to the processing space K1. As a result, gas corresponding to a flow rate difference (L2−L1) is introduced into the chamber 300 from the outside of the chamber 300 via the introduction port 362. Then, the gas corresponding to the flow rate difference (L2−L1) is supplied from the supplier 380 to the processing space K1.

### (Step S2: Placing Wafer)

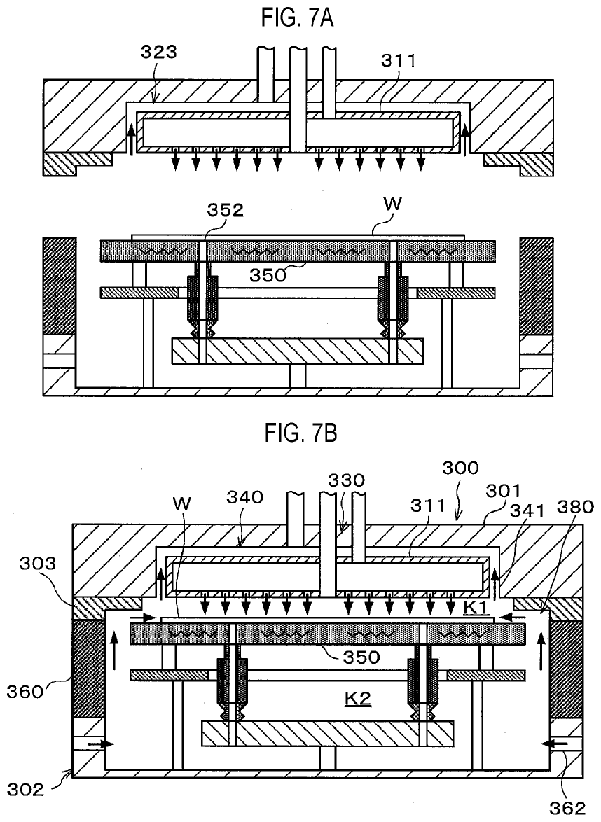

Subsequently, the wafer W on which the metal-containing resist film is formed is placed on the hot plate 350. Specifically, as shown in FIG. 6B, the upper chamber 301 is raised while the exhaust by the peripheral exhauster 340 and the supply of the reactive gas from the shower head 311 continue. Thereafter, the wafer W is transferred above the hot plate 350 by the wafer transfer device 33. Subsequently, the lifting pins (not shown) are raised and lowered so that the wafer W is transferred from the transfer device 30 to the lifting pins and from the lifting pins to the hot plate 350. As shown in FIG. 7A, the wafer W is placed on the hot plate 350. Thereafter, the wafer W is adsorbed onto the hot plate 350 via the adsorption holes 352.

### (Step S3: Heating)

Subsequently, while the exhaust by the peripheral exhauster 340 and the supply of the reactive gas from the shower head 311 continue, the wafer W on the hot plate 350 is heated for a predetermined period of time at a temperature Tt at which a sublimate containing metal, that is, a metal-containing sublimate, is not generated from the metal-containing resist film.

### (Step S3a: Beginning of Heating)

Specifically, as shown in FIG. 7B, the upper chamber 301 is lowered so that the rectifying member 303 comes into contact with the support ring 360 of the lower chamber 302 and the chamber 300 is brought into a closed state. Thus, the heating of the wafer W on the hot plate 350, that is, the PEB treatment, begins at the above-mentioned heating temperature Tt for a predetermined period of time Jt.

Specifically, under an assumption that Step S3 is performed while a reactive fluid is not supplied, the above-mentioned heating temperature Tt is a temperature at which insolubilization (that is, reaction) of the metal-containing resist becomes insufficient due to lack of the reaction within the metal-containing resist film, and thus, a pattern dimension of the metal-containing resist formed by the developing treatment after the PEB treatment becomes smaller than a target value. More specifically, the heating temperature Tt is, for example, less than 180 degrees C. The heating temperature Tt may be equal to or lower than a boiling point of a solvent in the metal-containing resist. The boiling point of the solvent in the metal-containing resist is, for example, 130 degrees C. Further, the heating temperature Tt is, for example, 80 degrees C. or higher. By setting the heating temperature to 80 degrees C. or higher, in-plane uniformity of the temperature of the hot plate 350 may be easily achieved.

Until a first predetermined period of time J1 (<Jt) has elapsed from the beginning of the PEB treatment, the exhaust by the central exhauster 330 is not performed, and the exhaust by the peripheral exhauster 340 and the supply of the reactive gas from the shower head 311 are performed. In this process, the exhaust by the peripheral exhauster 340 and the supply of the reactive gas from the shower head 311 are performed so that gas is supplied by the supplier 380. Specifically, for example the exhaust flow rate L2 of the gas exhausted from the processing space K1 by the peripheral exhauster 340 is controlled to be larger than the discharge flow rate L1 of the gas discharged from the shower head 311 to the processing space K1. As a result, the gas corresponding to the flow rate difference (L2−L1) is introduced into the chamber 300 from the outside of the chamber 300 via the introduction port 362. The gas corresponding to the flow rate difference (L2−L1) is then supplied from the supplier 380 to the wafer W on the hot plate 350. The flow rate of the gas supplied from the supplier 380 to the wafer W on the hot plate 350 is substantially uniform over a circumferential direction. The introduction port 362 may be said to be a gas introduction portion for introducing gas into the processing space K1 at a position below the hot plate 350.

Further, the gas supplied from the supplier 380 to the processing space K1 is directed toward the wafer W and moves to the exhaust port 341 to form an upward flow. This makes it possible to prevent a sublimate from adhering to the back surface or bevel of the wafer W, as will be described later.

The first predetermined period of time J1 is set to the extent that the metal-containing resist film on the wafer W is solidified to a desired level. In other words, the first predetermined period of time J1 is set to the extent that the condensation of the metal-containing resist on the wafer W progresses to a desired level. Further, information on the first predetermined period of time J1 is stored in a storage (not shown).

### (Step S3b: Beginning of Central Exhaust)

When the first predetermined period of time J1 has elapsed from the beginning of the PEB treatment, the exhaust by the central exhauster 330 begins while the exhaust by the peripheral exhauster 340 and the supply of the reactive gas from the shower head 311 continue.

### (Step S3c: Stopping PEB Treatment)

When a second predetermined period of time J2 has elapsed from the beginning of the exhaust by the central exhauster 330, the PEB treatment ends. Specifically, for example, the upper chamber 301 is raised so that the chamber 300 is brought into an open state. In this case, for example, the exhaust by the central exhauster 330, the exhaust by the peripheral exhauster 340, and the supply of the reactive gas from the shower head 311 continue. The second predetermined period of time J2 is set to the extent that the metal-containing resist film on the wafer W is solidified to a desired level. Information on the second predetermined period of time J2 is stored in the storage (not shown).

Further, the first predetermined period of time J1 and the second predetermined period of time J2 are set as follows. In other words, a ratio of a time duration required for the exhaust by the central exhauster 330 to a total time duration required for the PEB treatment (that is, the above-described predetermined period of time Jt) is set to be 1/20 to ½. More specifically, when the total time duration of the PEB treatment is 60 seconds, the time duration required for the exhaust by the central exhauster 330 is set to be 3 seconds to 30 seconds. The total time duration required for the PEB treatment (that is, the above-described predetermined period of time Jt) is, for example, a time duration until the upper chamber 301 is raised to open the chamber 300 after the wafer W is placed on the hot plate 350 and then the upper chamber 301 is lowered to close the chamber 300.

As in Step S3, when the wafer W is heated for a predetermined period of time at a temperature at which no metal-containing sublimate is generated from the metal-containing resist film, that is, when the PEB treatment is performed at a low temperature at which no metal-containing sublimate is generated from the metal-containing resist film, the reaction within the metal-containing resist film by the PEB treatment may be insufficient as described above.

In order to compensate for this lack of the reaction, the present inventors conducted extensive studies and found the following. That is, unlike the embodiment, in an example (hereinafter referred to as Comparative Example) in which gas containing an ambient atmosphere of the heat-treating apparatus 200 (specifically, an ambient atmosphere of the wafer processing system), the temperature and humidity of which are approximately equal to the temperature and humidity in the ambient atmosphere of the chamber 300, is supplied from the shower head 311 and the supplier 380, it was found that the state of the ambient atmosphere of the heat-treating apparatus affects results of the PEB treatment. Specifically, it was found that, in Comparative Example, as shown in FIG. 9, the higher the concentration of the carbon dioxide in the ambient atmosphere of the heat-treating apparatus, the smaller the space width of the line-and-space resist pattern obtained by the developing treatment after the PEB treatment. That is, as the concentration of the carbon dioxide in the gas supplied from the shower head 311 and the supplier 380 to the processing space K1 increases, the reaction within the metal-containing resist film by the PEB treatment (specifically, a condensation reaction of the metal-containing resist) proceeds. It was also found that, as shown in FIG. 10, the space becomes narrower as the humidity (that is, the concentration of the moisture) in the ambient atmosphere of the heat-treating apparatus increases. That is, it was found that the higher the concentration of the moisture in the gas supplied from the shower head 311 and the supplier 380 to the processing space K1, the more the reaction within the metal-containing resist film (specifically, the condensation reaction of the metal-containing resist) by the PEB treatment proceeds.

Taking this into consideration, in this embodiment, during the PEB treatment, that is, in Step S3, the reactive gas in which the concentration of at least one of the carbon dioxide or the moisture is higher than that in the atmosphere is supplied to the process space K1. Accordingly, in this embodiment, an insufficient reaction within the metal-containing resist film is compensated for by performing heating at a low temperature at which no metal-containing sublimate is generated from the metal-containing resist film during the PEB treatment. The results shown in FIGS. 9 and 10 also show that contribution of the carbon dioxide to the reaction within the metal-containing resist film is higher than the contribution of the moisture to the reaction.

Further, as in Step S3a, when only the exhaust by the peripheral exhauster 340 is

performed without the exhaust by the central exhauster 330, a flow of the reactive gas moving in a radial direction toward the peripheral portion of the wafer W is formed along the front surface of the wafer W in the vicinity of the front surface of the wafer W. In contrast, when the exhaust by the central exhauster 330 is also performed as in Step S3b, the gas does not flow along the front surface of the wafer W and flows upward from the peripheral portion of the wafer W toward the center of the wafer W. As a result, a gap between a boundary layer of an airflow of the gas toward the central exhauster 330 and the front surface of the wafer W varies in the wafer plane W. This causes a fluctuation in volatilization volume from the metal-containing resist film on the wafer W. Such a fluctuation in volatilization volume adversely affects the in-plane uniformity of film thickness on the wafer W at an initial stage of the PEB treatment when the solidification does not progress and thus the volatilization volume is large.

Therefore, in Step S3a, until the first predetermined period of time J1 has elapsed from the beginning of the PEB treatment, the exhaust by the central exhauster 330 is not performed, and the exhaust by the peripheral exhauster 340 and the supply of the reactive gas from the shower head 311 are performed.

Further, in Step S3a, since the gas is supplied from the supplier 380 to the processing space K1, the gas directed from the supplier 380 toward the wafer W moves to the exhaust port 341 to form an upward flow in the vicinity of the wafer W. In this case, the reactive gas discharged from the shower head 311 toward the wafer W and moving along the front surface of the wafer W also moves upward together with the above-mentioned upward flow and is exhausted to the outside via the exhaust port 341. Therefore, even if a metal-containing volatile substance is generated from the metal-containing resist film, the metal-containing volatile substance is exhausted to the outside together with the upward flow, and thus, may be suppressed from adhering to the back surface of bevel of the wafer W.

Further, in Step S3b, by performing the exhaust by the central exhauster 330, a flow of the reactive gas from the outer periphery of the wafer W toward the center of the wafer W is formed in the vicinity of the front surface of the wafer W. Thus, the reactive gas which may contain the volatile substance in the vicinity of the front surface of the wafer W is exhausted even via the central exhauster 330. Further, the amount of the gas exhausted by the central exhauster 330 may be larger than the amount of the gas exhausted by the peripheral exhauster 340. In this case, the reactive gas which may contain the volatile substance in the vicinity of the front surface of the wafer W is mainly discharged from the central exhauster 330. Therefore, it is possible to further suppress the metal-containing volatile substance from adhering to the back surface or bevel of the wafer W. In the operation of performing the exhaust by the central exhauster 330, since the solidification of the metal-containing resist film progresses, the influence of the airflow accompanying the exhaust on a variation in film thickness is small. Therefore, even if the exhaust by the central exhauster 330 is performed, the influence on the in-plane uniformity of the film thickness is small.

Almost all of a volatile substance of a solvent of the metal-containing resist, which contains metal, may be collected during prebaking, so that no volatile substance is substantially generated during the PEB treatment.

### (Step S4: Unloading Wafer)

After Step S3, the wafer W is removed from the hot plate 350 and unloaded outward from the heat-treating apparatus 200 in a reverse order of the procedure of loading the wafer W.

### <Main Effects of Present Embodiment>

As described above, in this embodiment, in the PEB treatment on the wafer W on which the metal-containing resist film has been formed and has been subjected to the exposure treatment, the wafer W is heated for a predetermined period of time at a low temperature at which a metal-containing sublimate is not generated from the metal-containing resist film. Therefore, according to the present embodiment, the contamination of the wafer W or other devices such as the heat-treating apparatus 200 caused by the metal-containing sublimate may be suppressed. Further, in the present embodiment, in the PEB treatment, a reactive fluid that promotes the reaction within the metal-containing resist film in which the concentration of at least one of the carbon dioxide or the moisture is higher than that in the atmosphere is supplied to the processing space Kl during the heating. By performing the heating at a low temperature as described above, it is possible to compensate for an insufficient reaction within the metal-containing resist film. This makes it possible to perform the PEB treatment at a good level.

Specifically, the reaction within the metal-containing resist film may be sufficiently promoted by the PEB treatment without increasing the exposure amount. That is, according to the present embodiment, it is possible to perform the PEB treatment on the wafer W at a good level while suppressing the contamination of the wafer W or other devices caused by the metal-containing sublimate during the PEB treatment.

Since the metal-containing resist is affected by surrounding moisture, the condensation of the metal-containing resist progresses until the PEB treatment is performed after exposure. In addition, the degree of progress of the condensation of the metal-containing resist varies depending on a length of time duration until the PEB treatment is performed after exposure. In the embodiment, since the reactive fluid that promotes the reaction within the metal-containing resist film is supplied to the processing space Kl during the PEB treatment, the reaction within the metal-containing resist film may proceed by the PEB treatment until the reaction within the metal-containing resist film is almost completed regardless of the degree of progress of the condensation of the metal-containing resist until the PEB treatment is performed. Therefore, according to the present embodiment, it is possible to suppress a variation in results of the PEB treatment depending on the length of time duration until the PEB treatment is performed after exposure.

Further, according to the present embodiment, since the metal-containing sublimate may be suppressed from occurring, the amount of metal in the metal-containing resist film may be increased, thereby improving an etching resistance of the metal-containing resist film.

### <Another Example of Reactive Gas Supply Mechanism>

FIG. 11 is a diagram showing another example of the reactive gas supply mechanism. A gas supply mechanism 320A of FIG. 11 includes a source 400 of carbon dioxide-containing gas (e.g., carbon dioxide gas) having a carbon dioxide concentration higher than that in the atmosphere, a source 401 of moisture-containing gas (e.g., vapor) having a moisture concentration higher than that in the atmosphere, a supply pipe 402 which connects the source 400 and a supply pipe 314, and a supply pipe 403 which connects the source 401 and the supply pipe 314. The supply pipe 402 is provided with a supply equipment group 404 including an opening/closing valve, a flow rate control valve, and the like, which control the flow of the carbon dioxide-containing gas. Further, the supply pipe 403 is provided with a supply equipment group 405 including an opening/closing valve, a flow rate control valve, and the like, which control the flow of the moisture-containing gas. The supply equipment groups 404 and 405 are controlled by the controller 100.

The gas supply mechanism 320A supplies, for example, a mixed gas of the carbon dioxide-containing gas from the source 400 and the moisture-containing gas from the source 401 to the shower head 311. This mixed gas may include a carrier gas (e.g., a nitrogen gas). Further, the gas supply mechanism 320A may supply either the carbon dioxide-containing gas from the source 400 or the moisture-containing gas from the source 401 to the shower head 311.

### <Another Example 1 of Supply of Reactive Gas During PEB Treatment>

The metal-containing resist reacts with moisture to become hydroxide, and reacts with carbon dioxide to become hydrogen carbonate. During the PEB treatment, the metal-containing resist that has been converted into the hydroxide and the metal-containing resist that has been converted into the hydrogen carbonate are condensed by heat or the like, so that the metal-containing resist is insolubilized in a developing solution. During the condensation described above, water and carbon dioxide are generated. Thus, when the amount of the gas exhausted by the central exhauster 330 is increased by performing the exhaust by the central exhaust from Step S3b of Step S3, the concentration of the carbon dioxide and the concentration of the moisture in the atmosphere may be increased in the center of the wafer W rather than the outer periphery of the wafer W.

As described above, the contribution of the carbon dioxide to the reaction within the metal-containing resist film is greater than the contribution of the moisture to the reaction within the metal-containing resist film. Therefore, there is no matter even if the concentration of the moisture in the atmosphere is higher at the center of the wafer W than at the outer periphery of the wafer W. However, when the concentration of the carbon dioxide in the atmosphere is higher at the center of the wafer W than at the outer periphery of the wafer W, the reaction within the metal-containing resist may more proceed at the center of the wafer W than at the outer periphery of the wafer W.

Therefore, in a time duration in which the exhaust by the central exhauster 330 is increased, the ratio of the moisture to the carbon dioxide in the reactive gas may be set to be higher than in a time duration before that time duration. Specifically, for example, in Step S3b in which the exhaust by the central exhauster 330 and the exhaust by the peripheral exhauster 340 are performed, the ratio of the moisture to the carbon dioxide in the reactive gas supplied to processing space K1 may be increased as compared to Step S3a in which the exhaust by the peripheral exhauster 340 is performed. This makes it possible to prevent the amount of the reaction within the metal-containing resist film from becoming uneven in the wafer plane. Specifically, it is possible to suppress the amount of the reaction within the metal-containing resist film from more progressing in the center of the wafer W than the outer periphery of the wafer W.

The exhaust by the central exhauster 330 is performed to, for example, collect the metal-containing volatile substance from the metal-containing resist film, or remove the gas generated by the reaction within the metal-containing resist film, that is, outgas.

Examples of a method of increasing the ratio of the moisture to the carbon dioxide in the reactive gas may include a method of increasing a concentration of the moisture without changing a concentration of the carbon dioxide in the reactive fluid, a method of increasing a supply flow rate of the moisture-containing gas without changing a supply flow rate of the carbon dioxide-containing gas in the case where the gas supply mechanism 320A of FIG. 11 is used.

<Another Example 2 of Supply of Reactive Gas during PEB treatment>

In a case where a variation in concentration of the moisture in the reactive gas supplied to the processing space K1 in the wafer plane is smaller than a variation in concentration of the carbon dioxide in the reactive gas in the wafer plane, a ratio of the carbon dioxide to the moisture in the reactive fluid supplied to the processing space K1 may be decreased during the PEB treatment. Specifically, for example, only the carbon dioxide-containing gas may be supplied to the processing space K1 until halfway of the PEB treatment, and subsequently, the moisture-containing gas may be supplied to the processing space K1 until the end of the PEB treatment.

As a result, the wafer W is heated using a large amount of moisture having little variation in concentration in the wafer plane at the end of the PEB treatment. Thus, the reaction within the metal-containing resist film may be suppressed from varying in the wafer plane as compared with the case in which the wafer W is heated using a large amount of carbon dioxide having a large variation in concentration in the wafer plane at the end of the PEB treatment.

Further, as described above, the contribution of the carbon dioxide to the reaction within the metal-containing resist film is larger than the contribution of the moisture to the reaction within the metal-containing resist film. That is, the reactivity of the metal-containing resist to the carbon dioxide is greater than the reactivity of the metal-containing resist to water. Therefore, when the ratio of the carbon dioxide to the moisture in the reactive fluid supplied to the processing space K1 is lowered during the PEB treatment, a time required to obtain a desired reaction amount may be shortened as compared with the case in which the ratio is constantly lowered.

Further, by supplying only the carbon dioxide-containing gas to the process space K1 until halfway of the PEB treatment, and subsequently, supplying the moisture-containing gas to the process space K1 until the end of the PEB treatment, the following safety effect may also be achieved. That is, it is possible to prevent a worker who operates the heat-treating apparatus 200 after the PEB treatment from suffocating from the carbon dioxide-containing gas.

### <Other Modifications>

In the PEB treatment according to the embodiment, since the wafer W is heated for a predetermined period of time at a low temperature at which no metal-containing sublimate is generated from the metal-containing resist film, there are fewer volatile substances including metal generated during the heating. Thus, the exhaust by the central exhauster 330 may be omitted. Further, in the PEB treatment, after the wafer W is heated at a temperature at which no metal-containing sublimate is generated from the metal-containing resist film, the wafer W may be heated under other conditions (specifically, for example, at a relatively high temperature). In this case, the exhaust by the central exhauster 330 may be performed while the wafer W is heated under other conditions. The post-bake treatment may be performed on the wafer W after the PEB treatment. When the post-bake treatment is performed, the wafer W may be heated at a temperature lower than the temperature during the PEB treatment in the post-bake treatment.

Gas with higher humidity than humidity in the wafer transfer area 32 may be supplied in a down-flow manner within the wafer processing system 1. Such a high-humidity gas may be used as a moisture-containing gas, which is the reactive gas to be supplied to the processing space K1.

Further, the metal-containing resist film may be formed by a CVD method or an ALD method.

According to the present disclosure in some embodiments, it is possible to perform a heat treatment on a substrate at a good level while suppressing the substrate or other devices from contaminating due to a metal-containing sublimate generated from a metal-containing resist on the substrate.

The embodiments disclosed herein should be considered to be exemplary in all aspects and not limitative. The above-described embodiments may be omitted, replaced, or modified in various ways without departing from the scope and spirit of the appended claims. For example, constituent elements of the above-described embodiments may be combined arbitrarily. From any of these combinations, functions and effects of respective constituent elements of the combination are naturally obtained, and other functions and effects that are obvious to those skilled in the art are also obtained from the description in the present specification.

Further, the effects described in this specification are merely explanatory or illustrative, and are not restrictive. In other words, the technology according to the present disclosure may have other effects that are obvious to those skilled in the art from the description of this specification, in addition to or in place of the above effects.

In addition, the following configuration examples also belong to the technical scope of the present disclosure.

(1) A heat-treating method of performing a heat treatment on a substrate on which a film of a metal-containing resist film is formed and which is subjected to an exposure treatment, includes an operation of heating the substrate for a predetermined period of time at a heating temperature at which a metal-containing sublimate is not generated from the film of the metal-containing resist, wherein during the operation of heating the substrate, a reactive fluid in which a concentration of at least one of a carbon dioxide or moisture is higher than a concentration in an atmosphere to promote a reaction within the film of the metal-containing resist, is supplied to a processing space around the substrate.

(2) In the heat-treating method of (1) above, when the operation of heating the substrate

is performed in a state where the reactive fluid is not supplied, the heating temperature is a temperature at which the reaction within the film of the metal-containing resist is insufficient and an insolubilization of the metal-containing resist is insufficient so that a pattern dimension of the metal-containing resist formed by a developing treatment after the heat treatment is smaller than a target value.

(3) In the heat-treating method of (1) or (2) above, the concentration of the carbon dioxide and the concentration of moisture in the reactive fluid are higher than concentrations in an atmosphere.

(4) In the heat-treating method of any one of (1) to (3) above, the reactive fluid is a mixed gas of a carbonated water vapor and a carrier gas.

(5) In the heat-treating method of any one of (1) to (4) above, the operation of heating the substrate includes increasing an exhaust amount by a central exhaust in which the processing space is exhausted from above a central portion of the substrate in a plan view during the operation of heating the substrate; and in a first time duration in which the exhaust amount by the central exhaust is increased, setting a ratio of the moisture to the carbon dioxide in the reactive fluid to be higher than in a second time duration before the first time duration.

(6) In the heat-treating method of any one of (1) to (4) above, a ratio of the carbon dioxide to the moisture in the reactive fluid is lowered during the operation of heating the substrate.

(7) A heat-treating apparatus for performing a heat treatment on a substrate on which a film of a metal-containing resist is formed and which is subjected to an exposure treatment, includes: a heater configured to support and heat the substrate; a chamber having a processing space formed above the heater and in which the substrate under the heat treatment is accommodated; an exhauster configured to evacuate an interior of the processing space; a supplier configured to supply a reactive fluid for promoting a reaction within the film of the metal-containing resist to the interior of the processing space; and a controller, wherein the controller controls the heater to heat the substrate for a predetermined period of time at a heating temperature at which a metal-containing sublimate is not generated from the film of the metal-containing resist, and while heating the substrate, the reactive fluid in which a concentration of at least one of a carbon dioxide or moisture is higher than a concentration in an atmosphere, is supplied to the processing space.

(8) A non-transitory computer-readable storage medium stores a program that causes a heat-treating apparatus to execute, by a computer, a heat-treating method of performing a heat treatment on a substrate on which a film of a metal-containing resist is formed and which is subjected to an exposure treatment, wherein the heat-treating method comprises heating the substrate for a predetermined period of time at a heating temperature at which a metal-containing sublimate is not generated from the film of the metal-containing resist, and during the heating of the substrate, the reactive fluid in which a concentration of at least one of a carbon dioxide or moisture is higher than a concentration in an atmosphere, is supplied to the processing space.

What is claimed is:

1. A heat-treating method of performing a heat treatment on a substrate on which a film of a metal-containing resist film is formed and which is subjected to an exposure treatment, the heat-treating method comprising:
an operation of heating the substrate for a predetermined period of time at a heating temperature at which a metal-containing sublimate is not generated from the film of the metal-containing resist,
wherein, during the operation of heating the substrate, a reactive fluid in which a concentration of at least one of a carbon dioxide or moisture is higher than a concentration in an atmosphere to promote a reaction within the film of the metal-containing resist, is supplied to a processing space around the substrate.

2. The heat-treating method of claim 1, wherein, when the operation of heating the substrate is performed in a state where the reactive fluid is not supplied, the heating temperature is a temperature at which the reaction within the film of the metal-containing resist is insufficient and an insolubilization of the metal-containing resist is insufficient so that a pattern dimension of the metal-containing resist formed by a developing treatment after the heat treatment is smaller than a target value.

3. The heat-treating method of claim 1, wherein the concentration of the carbon dioxide and the concentration of moisture in the reactive fluid are higher than concentrations in an atmosphere.

4. The heat-treating method of claim 1, wherein the reactive fluid is a mixed gas of a carbonated water vapor and a carrier gas.

5. The heat-treating method of claim 1, wherein the operation of heating the substrate includes:
increasing an exhaust amount by a central exhaust in which the processing space is exhausted from above a central portion of the substrate in a plan view during the operation of heating the substrate; and
in a first time duration in which the exhaust amount by the central exhaust is increased, setting a ratio of the moisture to the carbon dioxide in the reactive fluid to be higher than in a second time duration before the first time duration.

6. The heat-treating method of claim 1, wherein a ratio of the carbon dioxide to the moisture in the reactive fluid is lowered during the operation of heating the substrate.

7. A heat-treating apparatus for performing a heat treatment on a substrate on which a film of a metal-containing resist is formed and which is subjected to an exposure treatment, the heat-treating apparatus comprising:
a heater configured to support and heat the substrate;
a chamber having a processing space formed above the heater and in which the substrate under the heat treatment is accommodated;
an exhauster configured to evacuate an interior of the processing space;
a supplier configured to supply a reactive fluid for promoting a reaction within the film of the metal-containing resist to the interior of the processing space; and
a controller,
wherein the controller controls the heater to heat the substrate for a predetermined period of time at a heating temperature at which a metal-containing sublimate is not generated from the film of the metal-containing resist, and
wherein, while heating the substrate, the reactive fluid in which a concentration of at least one of a carbon dioxide or moisture is higher than a concentration in an atmosphere, is supplied to the processing space.

8. A non-transitory computer-readable storage medium storing a program that causes a heat-treating apparatus to execute, by a computer, a heat-treating method of performing a heat treatment on a substrate on which a film of a metal-containing resist is formed and which is subjected to an exposure treatment,
wherein the heat-treating method comprises heating the substrate for a predetermined period of time at a heating temperature at which a metal-containing sublimate is not generated from the film of the metal-containing resist, and
wherein during the heating of the substrate, the reactive fluid in which a concentration of at least one of a carbon dioxide or moisture is higher than a concentration in an atmosphere, is supplied to the processing space.
